(19) United States
(12) Patent Application Publication
(10) Pub. No.: US 2013/0148253 A1
(43) Pub. Date: Jun. 13, 2013

(54) SUBSTRATE TEMPERATURE ADJUSTING-FIXING DEVICE AND MANUFACTURING METHOD THEREOF

(71) Applicant: SHINKO ELECTRIC INDUSTRIES CO., LTD., Nagano (JP)

(72) Inventors: Hidehiro KOMATSU, Nagano (JP); Koji NAGAI, Nagano (JP); Akihiro KURIBAYASHI, Nagano (JP); Kazunori SHIMIZU, Nagano (JP)

(73) Assignee: SHINKO ELECTRIC INDUSTRIES CO., LTD., Nagano (JP)

(21) Appl. No.: 13/670,614

(22) Filed: Nov. 7, 2012

(30) Foreign Application Priority Data
Dec. 7, 2011 (JP) 2011-267932

(51) Int. Cl. H05K 7/20; H05K 13/00

(52) U.S. Cl. 361/234; 29/592.1

(57) ABSTRACT

A substrate temperature adjusting-fixing device includes an electro static chuck attracting and holding an object to be attracted; a base plate to which the electro static chuck is fixed; an adhesive layer formed between the electro static chuck and the base plate; and a heat insulation layer formed between the electro static chuck and the base plate, wherein the electro static chuck includes a base body having a mounting surface on which the object to be attracted is mounted, a heat generator directly formed on a surface opposite to the mounting surface of the base body, and an insulating layer formed to cover the heat generator.

### CROSS-REFERENCE TO RELATED APPLICATION

This patent application is based upon and claims the benefit of priority of the prior Japanese Patent Application No. 2011-267932 filed on Dec. 7, 2011, the entire contents of which are incorporated herein by reference.

### FIELD

The embodiments discussed herein are related to a substrate temperature adjusting-fixing device including an electro static chuck for attracting an object to be attracted which is mounted on a base body.

### BACKGROUND

For example, a substrate temperature adjusting-fixing device having an electro static chuck on a metallic base plate is proposed in Japanese Laid-open Patent Publication No. 05-347352. This substrate temperature adjusting-fixing device controls the temperature of the substrate while attracting and holding a substrate on a substrate attracting surface of the electro static chuck.

The electro static chuck is adhered to the upper surface of the base plate by, for example, a polyimide resin or a silicone resin. Further, a heat generator (a heater) may be formed in the electro static chuck as in Japanese Laid-open Patent Publication No. 2005-159018. For example, a film heater may be adhered to one surface of a heat equalizing plate as a heat generator. The other surface of the heat equalizing plate is adhered to the base body made of ceramics of the electro static chuck via the adhesive layer. The heat equalizing plate is made of, for example, aluminum. The heat equalizing plate is provided to equalize the entire temperature of the substrate.

### SUMMARY

According to an aspect of the embodiment, a substrate temperature adjusting-fixing device includes an electro static chuck attracting and holding an object to be attracted; a base plate to which the electro static chuck is fixed; an adhesive layer formed between the electro static chuck and the base plate; and a heat insulation layer formed between the electro static chuck and the base plate, wherein the electro static chuck includes a base body having a mounting surface on which the object to be attracted is mounted, a heat generator directly formed on a surface opposite to the mounting surface of the base body, and an insulating layer formed to cover the heat generator.

The object and advantages of the invention will be realized and attained by means of the elements and combinations particularly pointed out in the appended claims.

It is to be understood that both the foregoing general description and the following detailed description are exemplary and explanatory and are not restrictive of the invention, as claimed.

### BRIEF DESCRIPTION OF THE DRAWINGS

FIG. 1 is a cross-sectional view of an exemplary substrate temperature adjusting-fixing device of the first embodiment;

FIG. 2 is a view of the exemplary substrate temperature adjusting-fixing device of the first embodiment illustrating a manufacturing process thereof;

FIG. 3 is another view of the exemplary substrate temperature adjusting-fixing device of the first embodiment illustrating a manufacturing process thereof;

FIG. 4 is another view of the exemplary substrate temperature adjusting-fixing device of the first embodiment illustrating a manufacturing process thereof;

FIG. 5 is another view of the exemplary substrate temperature adjusting-fixing device of the first embodiment illustrating a manufacturing process thereof;

FIG. 6 is a cross-sectional view of an exemplary substrate temperature adjusting-fixing device of the comparative example;

FIG. 7 is a cross-sectional view of an exemplary substrate temperature adjusting-fixing device of the second embodiment; and

FIG. 8 is a cross-sectional view of an exemplary substrate temperature adjusting-fixing device of the third embodiment.

### DESCRIPTION OF EMBODIMENTS

It is difficult to use a film heater at a temperature of about 150° C. or higher because of heat resistance of the adhesive layer.

Preferred embodiments of the present invention will be described with reference to accompanying drawings. Where the same reference symbols are attached to the same parts, repeated description of the parts may be omitted.

### [a] First Embodiment

### [Structure of the Substrate Temperature Adjusting-Fixing Device]

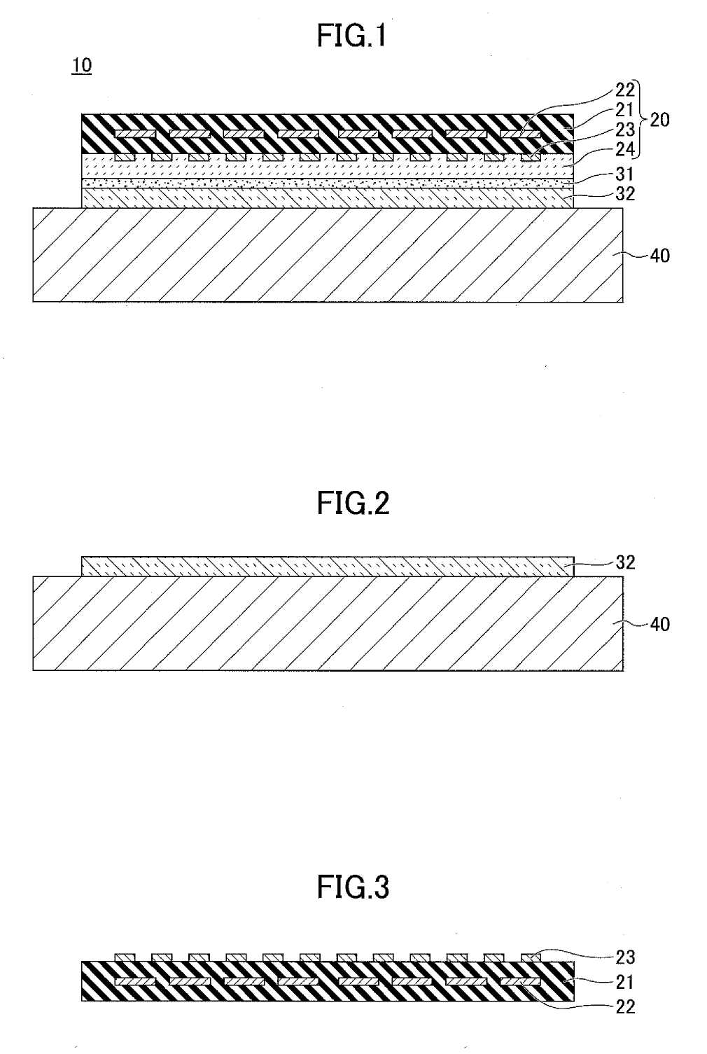

The structure of the substrate temperature adjusting-fixing device of the first embodiment is described. FIG. 1 is a cross-sectional view of an exemplary substrate temperature adjusting-fixing device of the first embodiment. Referring to FIG. 1, the substrate temperature adjusting-fixing device 10 includes an electro static chuck 20, an adhesive layer 31, a heat insulation layer 32 and a base plate 40.

The electro static chuck 20 includes a base body 21, an electrode 22, a heat generator 23, and a heat resisting layer 24. The electro static chuck 20 is an electro static chuck of a coulomb force type having a function of attracting and holding an object to be attracted. The electro static chuck 20 is fixed in the base plate 40 via an adhesive layer 31 and a heat insulation layer 32.

The base body 21 is a member having a mounting surface on which an object to be attracted substrate by the temperature adjusting-fixing device 10 is mounted. The object to be attracted may be a substrate (not illustrated) of a semiconductor wafer such as a silicon wafer. The base body 21 is made of ceramics such as Al₂O₃ and AlN. For example, the thickness of the base body 21 may be about 1 μm to about 20 μm. The outer diameter of the base body 21 is, for example, 6 inches, 8 inches, 12 inches, 18 inches, or the like.

The relative permittivity (1 KHz) of the base body 21 is, for example, about 9 to 10. The volume resistivity of the base body 21 is, for example, about 10¹² Ωm to about 10¹⁸ Ωm. The mounting surface of the base body 21 may be embossed. By embossing the mounting surface of the base body 21, it is possible to reduce particles adhering to the back surface of the substrate (not illustrated) which is the object to be attracted.

The electrodes 22 are in a shape of a thin film and are built in the base body 21. The electrode 22 is connected to a direct current power source (not illustrated) provided outside the substrate temperature adjusting-fixing device 10 via a power supplying portion (not illustrated). When a predetermined voltage is applied from the direct current power source (not illustrated) via the power supplying portion (not illustrated) to the electrodes 22, coulomb force is generated between the temperature adjusting-fixing device 10 and the substrate (not illustrated) which is the object to be attracted thereby attracting and holding the substrate to and on the mounting surface of the base body 21. The stronger the adsorbing and holding force becomes, the higher the voltage applied to the electrodes 22 becomes. The electrode 22 may be in a monopolar shape or a bipolar shape. The material of the electrodes 22 may be tungsten, molybdenum, or the like.

The heat generator 23 is directly formed on the back surface of the base body 21 to have a predetermined pattern. The back surface is opposite to the mounting surface of the base body 21. The heat generator 23 generates heat when voltage is applied from the outside of the substrate temperature adjusting-fixing device 10 and heats the mounting surface of the base body 21 to be a predetermined temperature. The heat generator 23 can heat the temperature of the mounting surface of the base body 21 to be about 250° C. to about 300° C.

The material of the heat generator 23 is, for example, copper (Cu), tungsten (W), nickel (Ni), or the like. For example, the thickness of the heat generator 23 may be about 5 μm to about 30 μm. An effect of directly forming the heat generator 23 on the back surface of the base body 21 is described later.

The heat resisting layer 24 is an insulating layer formed on the back surface of the base body 21 so as to cover the heat generator 23. The material of the heat resisting layer 24 is preferably excellent in heat resistance (for example, 300° C. or higher) and insulation. The material of the heat resisting layer 24 may be an insulating resin such as polyimide, low-melting-point glass, inorganic bond containing an inorganic material such as alumina or silica, or the like. A coefficient of thermal expansion of the heat resisting layer 24 is preferably similar to the coefficient of thermal expansion of the base body 21. The thickness of the heat resisting layer 24 is, for example, about 30 μm to about 200 μm.

As described, by selecting a material having a high heatproof temperature, which can withstand the maximum temperature of the heat generator 23, for the heat resisting layer 24, the heat resisting layer 24 can withstand the maximum temperature of the heat generator 23, so that the temperature of the heat generator 23 is scarcely transmitted to the adhesive layer 31 and the heat insulation layer 32. Therefore, it becomes possible to improve a degree of freedom in selecting the materials of the adhesive layer 31 and the heat insulation layer 32. For example, materials having a low heatproof temperature (for example, about 150° C.) can be selected for the adhesive layer 31 and the heat insulation layer 32.

The adhesive layer 31 is provided to fix the electro static chuck 20 to the base plate 40. The adhesive layer 31 can relax stress caused by a difference of coefficients of thermal expansion between the base body 21 of the electro static chuck 20 and the base plate 40. The material of the adhesive layer 31 is preferably excellent in plasticity. The material is, for example, an insulating resin such as silicon. The adhesive layer 31 may contain filler. As the contained amount of the filler is smaller, the plasticity can be improved easier. The thickness of the adhesive layer 31 is, for example, about 50 μm to about 500 μm.

The heat insulation layer 32 is provided to prevent heat generated by the heat generator 23 from escaping on the side of the base plate 40. The material of the heat insulation layer 32 is, for example, an insulating resin such as silicon containing the filler. By increasing the contained amount of the filler in the heat insulation layer 32, heat insulation can be improved. The thickness of the heat insulation layer 32 is preferably thick enough to perform predetermined heat insulation. The thickness of the heat insulation layer 32 is, for example, about 500 μm to about 2000 μm. Meanwhile, the same insulating resin may not be used for the adhesive layer 31 and the heat insulation layer 32.

The base plate 40 is provided to support the electrostatic chuck 20. The material of the base plate 40 is, for example, aluminum (Al) or the like. If the base plate 40 is made of Al, an alumite layer (a hard insulating layer) may be formed on the surface of the base plate 40. The base plate 40 includes a water path (not illustrated) which controls the temperature of the base body 21.

The water path (not illustrated) is connected to a cooling water control device (not illustrated) provided on the outside of the substrate temperature adjusting-fixing device 10. The cooling water control device (not illustrated) circulates cooling water through the water path (not illustrated). By cooling the base plate while circulating the cooling water, the base body 21 can be cooled via the adhesive layer 31 and the heat insulation layer 32.

A gas passage (not illustrated) may be provided inside the base body 21 and the base plate 40. An inert gas such as He or Ar is supplied into the gas passage (not illustrated) from a gas pressure control device (not illustrated), which is provided outside the substrate. Thus, the inert gas fills a space formed between the mounting surface of the base body 21 and the substrate (not illustrated). The inert gas improves heat conductivity between the base body 21 and the substrate (not illustrated) thereby uniformizing the temperature of the substrate (not illustrated).

### [Manufacturing Method of the Substrate Temperature Adjusting-Fixing Device]

The manufacturing method of the substrate temperature adjusting-fixing device of the first embodiment is described. FIG. 2 to FIG. 5 are plan views of an exemplary substrate temperature adjusting-fixing device of the first embodiment. Referring to FIG. 3 and FIG. 4, the substrate temperature adjusting-fixing device 10 illustrated in FIG. 1 is drawn upside down.

Referring to FIG. 2, the heat insulation layer 32 is formed on the base plate 40. Specifically, a thermosetting insulating resin such as silicon in a film-like shape containing the filler is laminated on the base plate 40. The insulating resin is heated so as to have a cure temperature or greater and hardened while the laminated insulating resin is pressed when necessary.

Specifically, a thermosetting insulating resin such as silicon in a liquid-like form or a paste-like form containing the filler is coated on the base plate 40 by, for example, a printing method or the like. Further, the coated insulating resin heated to have a temperature of the cure temperature or greater so as to be hardened. In order to make the heat insulation layer 32 be a predetermined thickness, coating and hardening are repeated plural times to laminate the insulating resin.

The thickness of the heat insulation layer 32 is, for example, about 500 μm to about 2000 μm. The base plate 40 may be made of, for example, aluminum (Al). The gas passage, the water path or the like may be formed before the process illustrated in FIG. 2, when necessary.

Next, in the process illustrated in FIG. 3, the heat generator 23 is directly formed on the other surface of the base body 21. The other surface of the base body 21 is opposite to the mounting surface of the base body 21. As described above, the electrodes 22 are integrated in the base body. At first, the base body 21 having the electrodes 22 integrated in it is prepared. The base body 21 having the electrodes 22 may be obtained by preparing plural green sheets, forming electrodes 22 having a predetermined pattern on the predetermined green sheets by a printing method, a sputtering method or the like, and sintering after laminating the green sheets.

The heat generator 23 can be formed by forming layers of copper (Cu) or nickel (Ni) or the like on an entire surface of the other surface of the base body 21 by, for example, electroless plating, and removing excessive portions by etching. Meanwhile, a portion without forming the heat generator 23 on the other side of the base body 21 may be covered by a mask such as the resist layer. Then, a layer made of copper (Cu) or nickel (Ni) may be formed only on a portion without being covered by the mask.

Further, instead of an electroless plating method, a sputtering method, a vapor-deposition method, a spray coating method, or the like may be used to form the heat generator 23 having a predetermined pattern on one side surface of the base body 21. For example, the thickness of the heat generator 23 is, for example, about 5 μm to about 30 μm.

Next, in the process illustrated in FIG. 4, the heat resisting layer 24 is formed to cover the heat generator 23 on the one surface of the base body 21. In order to form the heat resisting layer 24, a film-like material may be laminated and hardened or a liquid-like or paste-like material maybe coated and hardened in a manner similar to the process illustrated in FIG. 2. The material of the heat resisting layer 24 is, for example, an insulating resin such as polyimide, low-melting-point glass, alumina, an inorganic bond using an inorganic material such as silica, or the like. The thickness of the heat resisting layer 24 is, for example, about 30 μm to about 200 μm. With these processes, the electro static chuck 20 is completed.

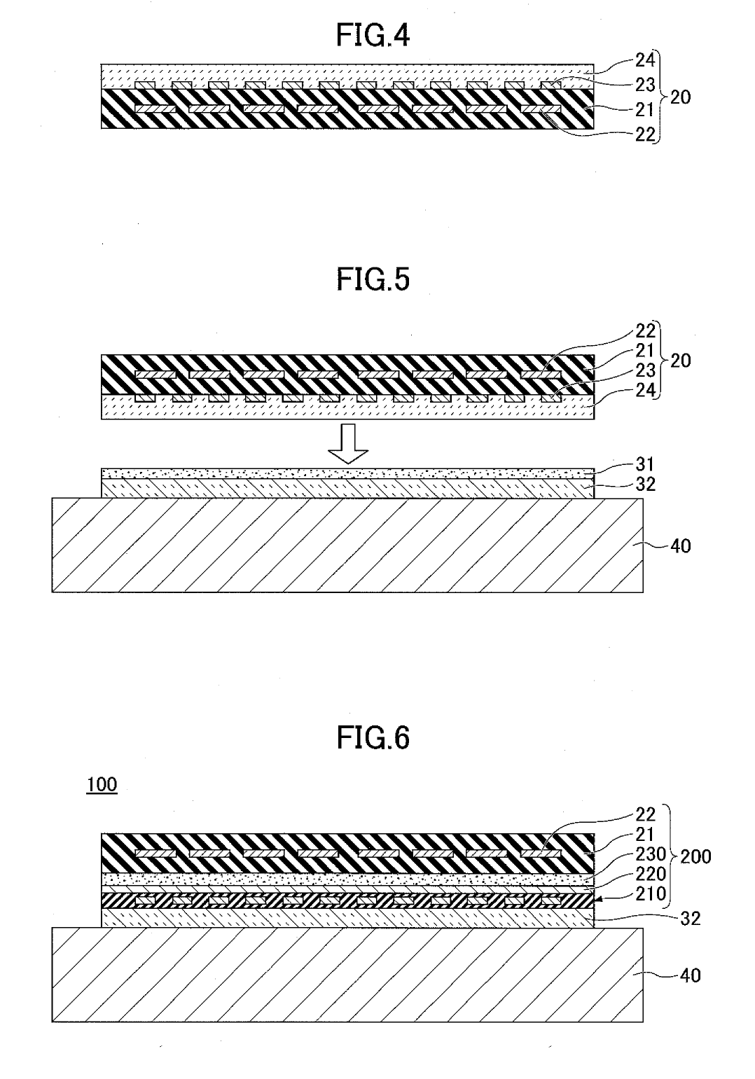

Referring to FIG. 5, the adhesive layer 31 is formed on the heat insulation layer 32 having the structure illustrated in FIG. 2. Before the adhesive layer 31 is hardened, the electro static chuck 20 is mounted in the adhesive layer 31. Thereafter, while pressing the electro static chuck 20 onto the side of the base plate 40 when necessary, the adhesive layer 31 is hardened by heating the adhesive layer to be the cure temperature or higher. With this, the substrate temperature adjusting-fixing device 10 illustrated in FIG. 1 is completed.

In order to form the adhesive layer 31, a film-like material may be laminated or a liquid-like or paste-like material may be coated in a manner similar to the process illustrated in FIG. 2. The material of the adhesive layer 31 is, for example, an insulative resin such as silicone. The thickness of the adhesive layer 31 is, for example, about 50 μm to about 500 μm. The adhesive layer 31 maintains plasticity after hardening.

Referring to a comparative example, an exemplary effect of the substrate temperature adjusting-fixing device 10 of the first embodiment is described. FIG. 6 is a cross-sectional view of an exemplary substrate temperature adjusting-fixing device of the comparative example. Referring to FIG. 6, the same reference symbols are given to the same components as those in FIG. 1 and redundant explanation is omitted.

Referring to FIG. 6, the substrate temperature adjusting-fixing device 100 of the comparative example includes an electro static chuck 200, a heat insulation layer 32 and a base plate 40. The electro static chuck 200 includes a base body 21, electrodes 22, a heat generator 210, a heat equalizing plate 220, and an adhesive layer 230. The electro static chuck 200 is an electro static chuck of a coulomb force type having a function of attracting and holding an object to be attracted. The electro static chuck 200 is fixed in the base plate 40 via a heat insulation layer 32.

The heat generator 210 is a heat generator (so-called “film heater”) in thin sheet-like form. The heat generator 210 is formed by coating a heat generating resistive element with an insulating material and attached to one surface of the heat equalizing plate 220. The other surface of the heat equalizing plate 220 is adhered to the base body 21 via the adhesive layer 230.

The heat equalizing plate 220 prevents thermal distribution from occurring in the substrate (not illustrated) which is heated by the heat generator 210 thereby substantially equalizing the temperature of the entire substrate. The material of the heat equalizing plate 220 is, for example, aluminum (Al). The thickness of the heat equalizing plate 220 is, for example, about 2 mm.

As described, since it is difficult to equalize the heat of the substrate with the film heater alone, the film heater is ordinarily attached to the heat equalizing plate 220. It is difficult to use the film heater at a high temperature of about 150° C. or higher because of heat resistance of the adhesive layer 230.

Meanwhile, in the substrate temperature adjusting-fixing device 10 of the first embodiment, the heat generator 23 is directly formed on the one surface of the base body 21 by electroless plating or the like without using the film heater 10. Because, with this structure, the heat generator 23 having a substantially uniform thickness is formed on one surface of the base body 21, thermal distribution hardly occurs and the heat equalizing plate may be omitted. Further, the heat generator 23 is covered by the heat insulation layer 24, and the adhesive layer 31 and the heat insulation layer 32 are provided between the heat insulation layer 24 and the base plate 40. Thus, a three-layered structure is formed between the heat generator 23 and the base plate 40. As a result, the operating temperature of the substrate temperature adjusting-fixing device 10 can be made higher than the ordinary (e.g., about 300° C. higher than about 150° C.).

Furthermore, the adhesive layer 31 having plasticity is provided between the electro static chuck 20 and the base plate 40. Therefore, even though stress is generated at a time of heating, the generated stress can be relaxed by the adhesive layer 31. Accordingly, from this point of view, the substrate temperature adjusting-fixing device 10 is suitable for use in a high temperature (e.g., 300° C.).

### [b] Second Embodiment

In a substrate temperature adjusting-fixing device of the second embodiment, the structure of the adhesive layer is different from that in the first embodiment. In the second embodiment, explanation of constructional elements the same as those described in the above description of the First Embodiment is omitted.

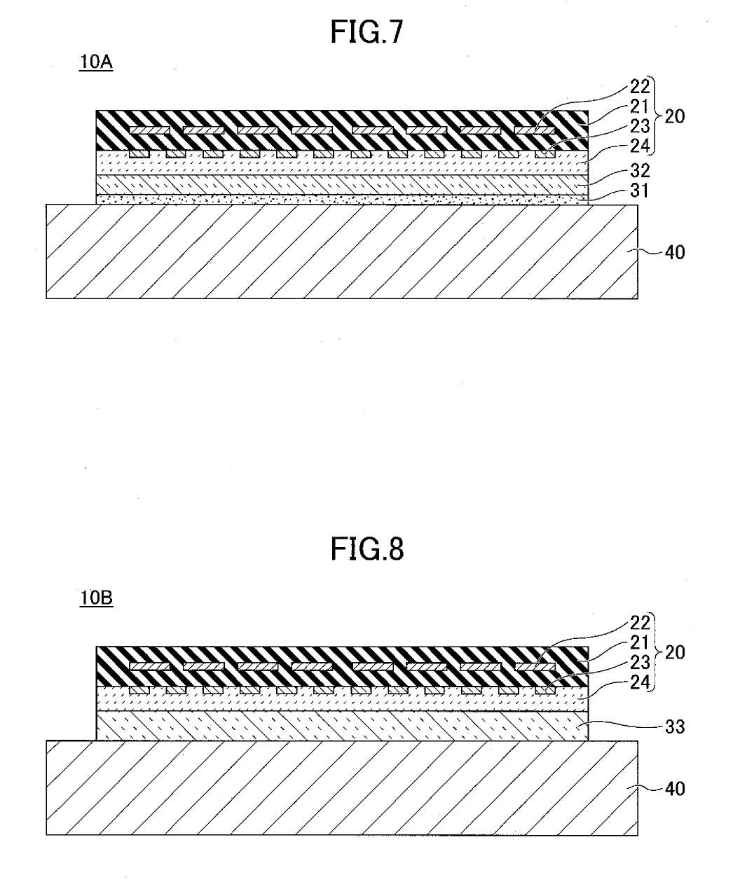

FIG. 7 is a cross-sectional view of an exemplary substrate temperature adjusting-fixing device of the second embodiment. Referring to FIG. 7, the order of arranging the adhesive layer 31 and the heat insulation layer 32 in the substrate temperature adjusting-fixing device 10A is different from the substrate temperature adjusting-fixing device 10 (see FIG. 1) of the first embodiment.

Said differently, the adhesive layer 31 is formed on the side of the base plate 40, and the heat insulation layer 32 is formed in the side of the electro static chuck 20. The materials and the thicknesses of the adhesive layer 31 and the heat insulation layer 32 are similar to those in the first embodiment.

Even if the order of laminating the adhesive layer 31 and the heat insulation layer 32 is inversed, the adhesive layer 31 and the heat insulation layer 32 can perform their functions, respectively. In a similar manner to the first embodiment, the adhesive layer 31 can relax stress caused by a difference of coefficients of thermal expansion of the electro static chuck 20 and the base plate 40, and the heat insulation layer 32 can prevent heat generated by the heat generator 23 from transferring onto the side of the base plate 40.

As described, the order of laminating the adhesive layer 31 and the heat insulation layer 32 may be inversed, and the effect similar to the first embodiment can be performed.

### [c] Third Embodiment

Within a substrate temperature adjusting-fixing device of the third embodiment, the structure of the adhesive layer is different from that in the first embodiment. In the third embodiment, explanation of constructional elements the same as those described in the above description are omitted.

FIG. 8 is a cross-sectional view of an exemplary substrate temperature adjusting-fixing device of the third embodiment. Referring to FIG. 8, the order of arranging the adhesive layer 31 and the heat insulation layer 32 in the substrate temperature adjusting-fixing device 10 (see FIG. 1) are replaced by an adhesive layer 33 in the substrate temperature adjusting-fixing device 10B of the third embodiment.

The adhesive layer 33 is made of only one layer. As described above, the same insulating resins may not be used for the adhesive layer 31 and the heat insulation layer 32, respectively. However, the same insulating resins having different contained amounts of filler may be used for the adhesive layer 31 and the heat insulation layer 32, respectively.

Depending on specifications of plasticity and heat insulation predetermined for the adhesive layer of the substrate temperature adjusting-fixing device, the adhesive layer formed by only one layer in which the contained amount of the filler is adjusted may be used. For example, the adhesive layer is made from a silicone resin containing a predetermined amount of the filler.

As described, depending on the predetermined specification, the adhesive layer formed by one layer appropriately having functions of both of the adhesive layer and the heat insulation layer may be used. In this case also, the effect similar to that in the first embodiment can be performed.

Within the first and second embodiments, the substrate temperature adjusting-fixing device is applied to the electro static chuck of a coulomb force type. However, the substrate temperature adjusting-fixing device may be applied to an electro static chuck of a Johnsen-Rahbek type in a manner similar thereto.

Further, the object to be attracted handled in the substrate temperature adjusting-fixing device of the first and second embodiments is, for example, a glass substrate used in a manufacturing process for a liquid crystal panel or the like.

According to the first and second embodiments, by directly forming the heater on a back surface of the base body of the electro static chuck and forming the heat resisting layer so as to cover the heater, the substrate temperature adjusting-fixing device which can be used at a temperature higher than before and the manufacturing method of the substrate temperature adjusting-fixing device are provided.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A substrate temperature adjusting-fixing device comprising:
an electro static chuck attracting and holding an object to be attracted;
a base plate to which the electro static chuck is fixed;
an adhesive layer formed between the electro static chuck and the base plate; and
a heat insulation layer formed between the electro static chuck and the base plate,
wherein the electro static chuck includes
a base body having a mounting surface on which the object to be attracted is mounted,
a heat generator directly formed on a surface opposite to the mounting surface of the base body, and
an insulating layer formed to cover the heat generator.

2. The substrate temperature adjusting-fixing device according to claim 1,
wherein the heat generator is made of a plating film.

3. The substrate temperature adjusting-fixing device according to claim 1,
wherein the adhesive layer is made of a material having a heatproof temperature lower than that of the insulating layer.

4. The substrate temperature adjusting-fixing device according to claim 1,
wherein the heat insulation layer, the adhesive layer, and the electro static chuck are laminated in this order on the base plate.

5. The substrate temperature adjusting-fixing device according to claim 1,
wherein the adhesive layer, the heat insulation layer, and the electro static chuck are laminated in this order on the base plate.

6. A substrate temperature adjusting-fixing device comprising:
an electro static chuck attracting and holding an object to be attracted;
a base plate to which the electro static chuck is fixed; and
an adhesive layer formed between the electro static chuck and the base plate;
wherein the electro static chuck includes
a base body having a mounting surface on which the object to be attracted is mounted,
a heat generator directly formed on a surface opposite to the mounting surface of the base body, and
an insulating layer formed to cover the heat generator.

7. The substrate temperature adjusting-fixing device according to claim 6,
wherein the heat generator is made of a plating film.

8. A manufacturing method of manufacturing a substrate temperature adjusting-fixing device comprising:
forming an electro static chuck attracting and holding an object to be attracted; and
fixing the electro static chuck to a base plate via an adhesive layer,
wherein the forming the electro static chuck includes
forming a base body having a mounting surface on which the object to be attracted is mounted,
forming a heat generator directly on a surface opposite to the mounting surface of the base body, and
forming an insulating layer so as to cover the heat generator.

9. The manufacturing method according to claim 8,
wherein, in the fixing the electro static chuck, the electro static chuck is fixed to the base plate not only via the adhesive layer but also via a heat insulation layer.

10. The manufacturing method according to claim 9,
wherein the forming the heat generator is to form a plating film on the surface opposite to the mounting surface.

11. The manufacturing method according to claim 9,
wherein the heat insulation layer, the adhesive layer, and the electro static chuck are laminated in this order on the base plate.

12. The manufacturing method according to claim 9,
wherein the adhesive layer, the heat insulation layer, and the electro static chuck are laminated in this order on the base plate.
